(19) United States
(12) Patent Application Publication
(10) Pub. No.: US 2018/0048302 A1
(43) Pub. Date: Feb. 15, 2018

(54) DRIVE CIRCUIT AND SEMICONDUCTOR DEVICE

(71) Applicant: Mitsubishi Electric Corporation, Tokyo (JP)

(72) Inventors: Kazuya HOKAZONO, Tokyo (JP); Akihisa YAMAMOTO, Tokyo (JP); Dong WANG, Tokyo (JP)

(73) Assignee: Mitsubishi Electric Corporation, Tokyo (JP)

(21) Appl. No.: 15/557,136

(22) PCT Filed: Jun. 22, 2015
(86) PCT No.: PCT/JP2015/067916

§ 371 Date: Sep. 11, 2017

(51) Int. Cl. H03K 17/08; H03K 3/011; H03K 17/284

(52) U.S. Cl. CPC H03K 17/08; H03K 17/284; H03K 3/011; H03K 2017/0806

(57) ABSTRACT

A drive circuit includes one constant voltage circuit for generating a first voltage and a second voltage, a first output circuit connected to the constant voltage circuit to receive the first voltage and the second voltage and receive a gate drive signal, a second output circuit connected to the constant voltage circuit to receive the first voltage and the second voltage and receive the gate drive signal, a first terminal connected to an output of the first output circuit, and a second terminal connected to an output of the second output circuit, wherein a voltage generated by the constant voltage circuit is applied to a plurality of semiconductor switching elements connected in parallel during switching.

### FIELD

This invention relates to a drive circuit for controlling a plurality of semiconductor switching elements and a semiconductor device including the drive circuit.

### BACKGROUND

Patent Document 1 discloses a technique in which the Miller voltage of a semiconductor switching element is sensed to control the gate voltage. The above-described technique increases the gate voltage during the turn-on of the semiconductor switching element to speed up turn-on operation, and adjusts the Miller time during turn-off, thus facilitating parallel connection between semiconductor switching elements.

Patent Document 2 discloses a method for preventing a semiconductor switching element from being deteriorated by reducing an overcurrent flowing through the semiconductor switching element. Specifically, the gate voltage of the semiconductor switching element is restricted to reduce a short-circuit current which can flow through the semiconductor switching element.

### PRIOR ART

### Patent Literature

Patent Literature 1: Japanese Patent Laid-Open No. H11-262243

Patent Literature 2: Japanese Patent Laid-Open No. 2009-71956

### SUMMARY

### Technical Problem

There are cases where a plurality of semiconductor switching elements such as IGBTs (Insulated Gate Bipolar Transistors) are connected in parallel to increase an output current. Preferably, the plurality of semiconductor switching elements connected in parallel are turned on at the same time and turned off at the same time. However, values of Vth may vary among the plurality of semiconductor switching elements, and a gate drive signal may be supplied to the plurality of semiconductor switching elements at different timings.

If a specific semiconductor switching element turns on faster than the other semiconductor switching elements, a current is concentrated on the “specific semiconductor switching element.” Moreover, if a specific semiconductor switching element turn off slower than the other semiconductor switching elements, a current is concentrated on the “specific semiconductor switching element.” As the output current increases, such an imbalance in the current becomes more significant, and damage to the semiconductor switching element becomes larger.

The technique of Patent Document 1 requires a circuit for sensing the gate voltage and a circuit for controlling the gate voltage for each semiconductor switching element, and therefore has a problem that an increase in the number of semiconductor switching elements connected in parallel leads to complicated control. Moreover, since the semiconductor switching elements connected in parallel share a gate interconnection, the technique of Patent Document 1 also has a gate oscillation problem.

The drive circuit disclosed in Patent Document 2 has a problem that if the drive circuit is provided for each of semiconductor switching elements connected in parallel, a gate drive signal is supplied to the plurality of semiconductor switching elements at different timings.

So far, sufficient studies have not been performed on the problem that variations in the timing of switching among a plurality of semiconductor switching elements connected in parallel cause a current to be concentrated on a specific one of the semiconductor switching elements.

The present invention has been accomplished to solve the above-described problems, and an object of the present invention is to provide a drive circuit and a semiconductor device which can prevent a large current from flowing through a specific one of a plurality of semiconductor switching elements connected in parallel during switching.

### Means for Solving the Problems

According to a present invention, a drive circuit includes one constant voltage circuit for generating a first voltage and a second voltage, a first output circuit connected to the constant voltage circuit to receive the first voltage and the second voltage and receive a gate drive signal, a second output circuit connected to the constant voltage circuit to receive the first voltage and the second voltage and receive the gate drive signal, a first terminal connected to an output of the first output circuit, and a second terminal connected to an output of the second output circuit, wherein the first output circuit applies the first voltage to the first terminal only during a predetermined first period when the gate drive signal rises; after the first period has elapsed, increases a voltage of the gate drive signal and applies the gate drive signal with the increased voltage to the first terminal; and applies the second voltage to the first terminal only during a predetermined second period when the gate drive signal falls, and the second output circuit applies the first voltage to the second terminal only during the first period when the gate drive signal rises; after the first period has elapsed, increases a voltage of the gate drive signal and applies the gate drive signal with the increased voltage to the second terminal; and applies the second voltage to the second terminal only during the second period when the gate drive signal falls.

According to a present invention, a semiconductor device includes one constant voltage circuit for generating a first voltage and a second voltage, a plurality of output circuits connected to the constant voltage circuit to receive the first voltage and the second voltage and receive a gate drive signal, a plurality of terminals connected to outputs of the plurality of output circuits, and a plurality of semiconductor switching elements connected to the plurality of terminals and connected in parallel, wherein the plurality of output circuits apply the first voltage to the plurality of terminals only during a predetermined first period when the gate drive signal rises; after the first period has elapsed, increase a voltage of the gate drive signal and apply the gate drive signal with the increased voltage to the plurality of terminals; and apply the second voltage to the plurality of terminals only during a predetermined second period when the gate drive signal falls.

According to another aspect of the present invention, a drive circuit includes a first constant voltage circuit for generating a first voltage and a second voltage, a second constant voltage circuit for generating a third voltage and a fourth voltage, a first output circuit connected to the first constant voltage circuit to receive the first voltage and the second voltage and receive a gate drive signal, a second output circuit connected to the second constant voltage circuit to receive the third voltage and the fourth voltage and receive the gate drive signal, a first terminal connected to an output of the first output circuit, and a second terminal connected to an output of the second output circuit, wherein the first output circuit applies the first voltage to the first terminal only during a predetermined first period when the gate drive signal rises; after the first period has elapsed, increases a voltage of the gate drive signal and applies the gate drive signal with the increased voltage to the first terminal, and applies the second voltage to the first terminal only during a predetermined second period when the gate drive signal falls, the second output circuit applies the third voltage to the second terminal only during the first period when the gate drive signal rises; after the first period has elapsed, increases a voltage of the gate drive signal and applies the gate drive signal with the increased voltage to the second terminal; and applies the fourth voltage to the second terminal only during the second period when the gate drive signal falls, and the first constant voltage circuit, the second constant voltage circuit, the first output circuit, and the second output circuit are formed in one IC.

According to another aspect of the present invention, a drive circuit includes a first constant voltage circuit for generating a first voltage and a second voltage, a second constant voltage circuit for generating voltages equal to the first voltage and the second voltage, a plurality of first output circuits connected to the first constant voltage circuit to receive the first voltage and the second voltage and receive a gate drive signal, a plurality of second output circuits connected to the second constant voltage circuit to receive the first voltage and the second voltage and receive the gate drive signal, and a plurality of terminals connected to outputs of the plurality of first output circuits and outputs of the plurality of second output circuits, wherein the plurality of first output circuits and the plurality of second output circuits apply the first voltage to the plurality of terminals only during a predetermined first period when the gate drive signal rises; after the first period has elapsed, increase a voltage of the gate drive signal and apply the gate drive signal with the increased voltage to the plurality of terminals; and apply the second voltage to the plurality of terminals only during a predetermined second period when the gate drive signal falls, and the first constant voltage circuit, the second constant voltage circuit, the plurality of first output circuits, and the plurality of second output circuits are formed in one IC.

Other features of the present invention will become apparent from the following description.

### Advantageous Effects of Invention

In accordance with this invention, a voltage generated by a single constant voltage circuit is applied to a plurality of semiconductor switching elements connected in parallel during switching. Accordingly, a large current can be prevented from flowing through a specific one of the semiconductor switching elements.

### BRIEF DESCRIPTION OF THE DRAWINGS

FIG. 1 is a block diagram of a drive circuit according to Embodiment 1.

FIG. 2 is a circuit diagram showing one example of the first output circuit.

FIG. 3 is a waveform diagram.

FIG. 4 is a circuit diagram of the constant voltage circuit according to Embodiment 2.

FIG. 5 is a block diagram of the drive circuit according to Embodiment 3.

FIG. 6 is a block diagram of the drive circuit according to Embodiment 4.

FIG. 7 is a circuit diagram of a semiconductor device according to Embodiment 5.

FIG. 8 is a block diagram of a drive circuit according to Embodiment 6.

FIG. 9 is a block diagram of a drive circuit according to Embodiment 7.

### DESCRIPTION OF THE EMBODIMENTS

Drive circuits and semiconductor devices according to embodiments of the present invention will be described with reference to the drawings. The same or corresponding components will be denoted by the same reference signs, and the repetition of explanation thereof may be omitted.

### Embodiment 1

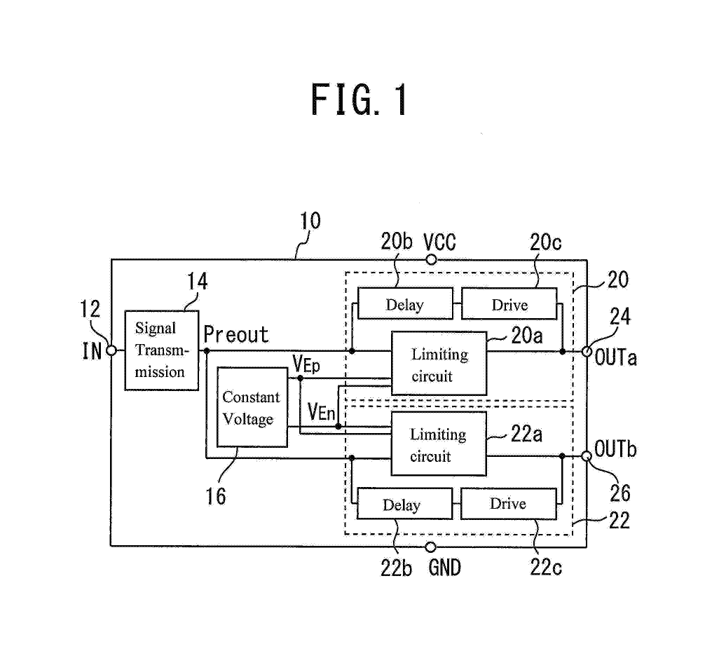

FIG. 1 is a block diagram of a drive circuit 10 according to Embodiment 1 of the present invention. The drive circuit 10 is formed as one IC (integrated circuit). The drive circuit 10 includes an input terminal 12 for receiving a gate drive signal from the outside, and first and second terminals 24 and 26 for outputting gate drive signals to the outside. A gate of a first semiconductor switching element is connected to the first terminal 24, and a gate of a second semiconductor switching element connected in parallel with the first semiconductor switching element is connected to the second terminal 26. Examples of the first and second semiconductor switching elements include, but not limited to, IGBTs. The drive circuit 10 is intended to control a plurality of semiconductor switching elements connected in parallel.

A signal transmission circuit 14 is connected to the input terminal 12. The signal transmission circuit 14 generates a gate drive signal (Preout) in synchronization with a signal inputted from the input terminal 12. The signal transmission circuit 14 includes at least any one of a filter circuit, a delay circuit, and a level shifter circuit. A filter circuit is a circuit for removing noise contained in an inputted signal. A delay circuit is a circuit for setting a dead time (off period) provided so that semiconductor switching elements of upper and lower arms which are supposed to be alternately turned on and off in a repeated manner may be prevented from being simultaneously turned on and short-circuiting the power supply. A level shifter circuit is a circuit for increasing the signal level of a gate drive signal in the case where semiconductor switching elements to be controlled are elements of a type which are driven by high voltages. The signal transmission circuit 14 may be formed as desired.

The drive circuit 10 includes one constant voltage circuit 16 for generating a first voltage VEp and a second voltage VEn. The constant voltage circuit 16 may be provided outside the drive circuit. Whether the constant voltage circuit 16 is provided within or outside the drive circuit 10, just one constant voltage circuit is provided. The constant voltage circuit 16 may have any configuration as long as the constant voltage circuit 16 outputs the first voltage VEp and the second voltage VEn to the outside.

The drive circuit 10 includes a first output circuit 20 and a second output circuit 22. The first output circuit 20 is connected to the signal transmission circuit 14 and the constant voltage circuit 16 to receive a gate drive signal, the first voltage, and the second voltage. The second output circuit 22 is connected to the signal transmission circuit 14 and the constant voltage circuit 16 to receive the gate drive signal, the first voltage, and the second voltage. The first terminal 24 is connected to an output of the first output circuit 20. An output from the first output circuit 20 is applied to the first terminal 24. The second terminal 26 is connected to an output of the second output circuit 22. An output from the second output circuit 22 is applied to the second terminal 26.

The first output circuit 20 and the second output circuit 22 output output signals in synchronization with the gate drive signal Preout. Specifically, signals OUTa and OUTb at the first and second terminals 24 and 26 rise in synchronization with the rising of the gate drive signal Preout, and fall in synchronization with the falling of the gate drive signal Preout.

The first output circuit 20 includes a first limiting circuit 20a, a first delay circuit 20b, and a first drive circuit 20c. The second output circuit 22 includes a second limiting circuit 22a, a second delay circuit 22b, and a second drive circuit 22c.

The first limiting circuit 20a and the second limiting circuit 22a are circuits which receive the gate drive signal Preout and limit the voltage values of the output signals in synchronization with the gate drive signal Preout. Specifically, when the gate drive signal Preout rises, the rising of the output signals OUTa and OUTb is restricted to the first voltage VEp; and, when the gate drive signal Preout falls, the dropping of the output signals OUTa and OUTb is restricted to the second voltage VEn.

The first delay circuit 20b and the second delay circuit 22b are circuits for delaying the gate drive signal Preout. Delay times by which the first delay circuit 20b and the second delay circuit 22b delay the gate drive signal are supposed to be sufficiently long for variations in the timing of switching when the gate drive signal is supplied to the plurality of semiconductor switching elements at the same timing. In other words, the delay time is set to a time longer than a switching time difference caused by variations in characteristics among the plurality of semiconductor switching elements.

The first drive circuit 20c and the second drive circuit 22c are circuits for controlling the voltage values of the output signals OUTa and OUTb in a steady state (non-switching state). The first drive circuit 20c is driven by the gate drive signal Preout delayed by the first delay circuit 20b. The second drive circuit 22c is driven by the gate drive signal Preout delayed by the second delay circuit 22b.

Thus, the first output circuit 20 and the second output circuit 22 output the gate drive signal inputted from the signal transmission circuit 14. The signal transmission circuit 14, the constant voltage circuit 16, the first output circuit 20, and the second output circuit 22 are formed as one IC.

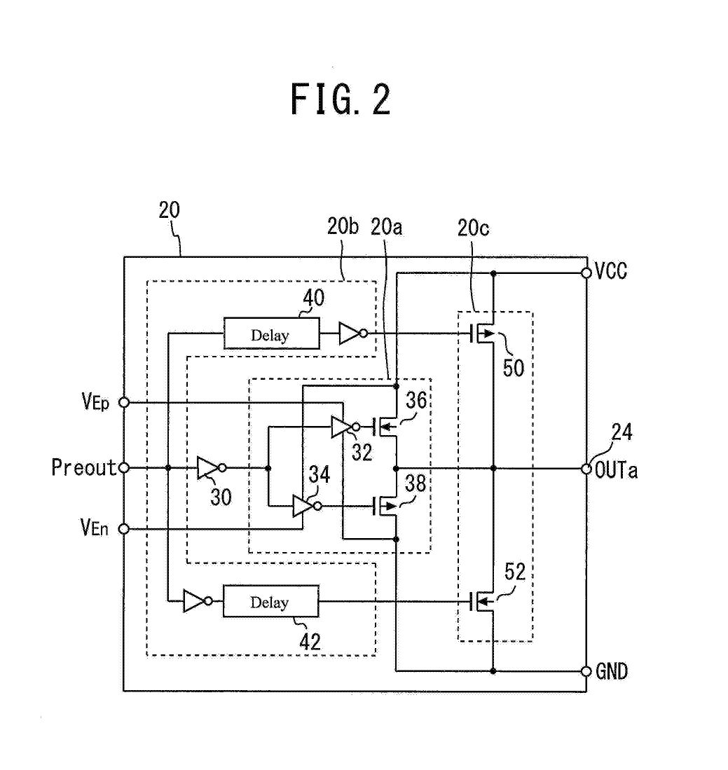

FIG. 2 is a circuit diagram showing one example of the first output circuit 20. The first voltage VEp, the gate drive signal Preout, and the second voltage VEn are inputted to the first output circuit 20. The first limiting circuit 20a is a source follower circuit. Specifically, the first limiting circuit 20a includes an NMOS 36 and a PMOS 38 connected as source followers. The NMOS 36 and the PMOS 38 are controlled by outputs from inverters 32 and 34, respectively.

The inverters 32 and 34 apply voltages to gates of the NMOS 36 and the PMOS 38 in synchronization with the gate drive signal Preout which has passed through an inverter 30. The supply voltage of the inverter 32 is the first voltage VEp. The inverter 32 changes the gate voltage of the NMOS 36 to the first voltage VEp when the gate drive signal Preout=H (High). On the other hand, a reference potential of the inverter 34 is the second voltage VEn. The inverter 34 changes the gate voltage of the PMOS 38 to the second voltage VEn when the gate drive signal Preout=L (Low). Thus, an output from the first limiting circuit 20a synchronizes with the gate drive signal Preout, and is restricted to voltage values corresponding to gate voltage values of the NMOS 36 and the PMOS 38.

The first voltage VEp and the second voltage VEn are set so that the value of a current concentrated on one of the plurality of semiconductor switching elements connected in parallel may be the breakdown voltage of the one of the semiconductor switching elements or less.

In FIG. 2, the first drive circuit 20c includes a PMOS 50 and an NMOS 52 connected in series. The PMOS 50 and the NMOS 52 are controlled by the gate drive signal Preout delayed by the first delay circuit 20b.

In FIG. 2, the first delay circuit 20b includes delay circuits 40 and 42. The delay circuits 40 and 42 delay inputted signals only when the signals rise. For example, when the gate drive signal

Preout rises, the gate drive signal is delayed by the delay circuit 40. The delayed gate drive signal is inverted by an NOT circuit (inverter) in a stage subsequent to the delay circuit 40 to be inputted to the PMOS 50.

Meanwhile, when the gate drive signal Preout falls, a signal inverted by an NOT circuit is delayed by the delay circuit 42. The delayed gate drive signal is inputted to the NMOS 52.

When the gate drive signal Preout rises, the first limiting circuit 20a applies the first voltage VEp to the first terminal 24 first, and the PMOS 50 is turned on after a specified delay time has elapsed. Meanwhile, when the gate drive signal Preout falls, the first limiting circuit 20a applies the second voltage VEn to the first terminal 24 first, and the NMOS 52 is turned on after a specified delay time has elapsed. In other words, during a period in which the gate drive signal Preout is delayed by the delay circuit 40 or 42, the voltage value at the first terminal 24 can be restricted to the first voltage VEp or the second voltage VEn.

It should be noted that the circuit configuration of the second output circuit 22 may be the same as that of the first output circuit 20, and therefore the explanation thereof will be omitted.

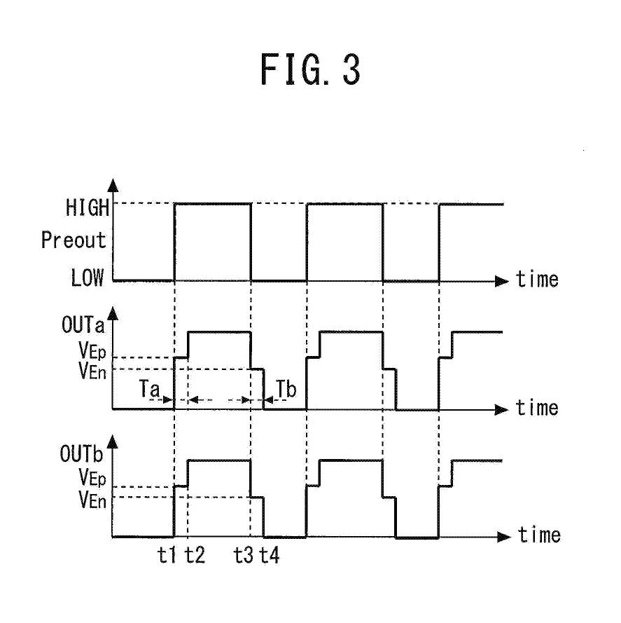

Next, the operation of the drive circuit 10 will be described with reference to a waveform diagram in FIG. 3. In FIG. 3, when the gate drive signal Preout rises, a first period Ta starts. In FIG. 3, the first period Ta is a period from time t1 to time t2. During the first period Ta, the first limiting circuit 20a applies the first voltage VEp to the first terminal 24. Moreover, the second limiting circuit 22a applies the first voltage VEp to the second terminal 26.

The first period Ta is equal to a period in which the gate drive signal is delayed by the first delay circuit 20b and the second delay circuit 22b. When the first period ends at time t2, a steady period from time t2 to time t3 starts. During the steady period, the gate drive signal delayed by the first delay circuit 20b is amplified by the first drive circuit 20c to be applied to the first terminal 24. The first drive circuit 20c amplifies the output of the first delay circuit 20b and applies the amplified output to the first terminal 24 during the period (steady period) after the first period Ta and before the start (time t3) of a second period.

During the steady period, the gate drive signal delayed by the second delay circuit 22b is amplified by the second drive circuit 22c to be applied to the second terminal 26. In the second drive circuit 22c, the output of the second delay circuit 22b is amplified, and the amplified signal is applied to the second terminal 26.

After that, the gate drive signal Preout falls at time t3. A period from time t3 to time t4 is the second period Tb. The first limiting circuit 20a applies the second voltage VEn to the first terminal 24 during the second period Tb. The second limiting circuit 22a applies the second voltage VEn to the second terminal 26 during the second period Tb. It should be noted that the second period Tb is equal to a period in which the gate drive signal is delayed by the first delay circuit 20b and the second delay circuit 22b.

In accordance with the present invention, when the gate drive signal Preout rises, the voltages applied to the first and second terminals 24 and 26 are restricted to the first voltage VEp; and, when the gate drive signal Preout falls, the voltages applied to the first and second terminals 24 and 26 are prevented from dropping below the second voltage VEn. Thus, the gate voltages of a plurality of semiconductor switching elements connected in parallel during switching can be restricted, and a large current can be prevented from flowing through a specific one of the semiconductor switching elements.

Specifically, when the plurality of semiconductor switching elements are turned on, a current is concentrated on one of the semiconductor switching elements which is turned on relatively earlier. Accordingly, by restricting the rising of the gate voltage of the semiconductor switching element, a large current can be prevented from flowing through the semiconductor switching element.

When the plurality of semiconductor switching elements are turned off, a current is concentrated on one of the semiconductor switching elements which is turned off relatively later. Accordingly, by restricting the dropping of the gate voltage of the semiconductor switching element which is turned off relatively earlier, a large current can be prevented from flowing through the specific semiconductor switching element.

Advantageous effects of the present invention will be specifically described by considering the case where two semiconductor switching elements connected in parallel are turned off. At the time of turn off, when any one (e.g., first semiconductor switching element) of the semiconductor switching elements connected in parallel is turned off earlier due to variations in Vth, a current which has been flowing through the first semiconductor switching element flows into the other semiconductor switching element (second semiconductor switching element) which is still in an on state. In other words, a current which has been flowing in an on state (steady period) is concentrated on the second semiconductor switching element. At this time, when the current flowing through the second semiconductor switching element becomes the breakdown voltage or more, the second semiconductor switching element may be deteriorated or broken.

However, in the drive circuit according to Embodiment 1 of the present invention, the dropping of the gate voltage of the first semiconductor switching element which is turned off earlier is restricted to the second voltage VEn. Thus, the value of a current flowing into the second semiconductor switching element can be restricted. The second voltage VEn is set so that the value of the current flowing into the second semiconductor switching element may be the breakdown voltage or less.

The delay times set in the first delay circuit 20b and the second delay circuit 22b need to be sufficiently long relative to variations (switching time difference) in switching of the plurality of semiconductor switching elements. However, if the delay times are made long, desired control cannot be realized. In Embodiment 1 of the present invention, to shorten the delay times, the plurality of output circuits (first output circuit 20 and second output circuit 22) are integrated within the one drive circuit 10. Further, since the gate drive signal Preout is supplied from the one signal transmission circuit 14 to the plurality of output circuits, there is almost no transmission delay difference between the gate drive signal inputted to the first delay circuit 20b and that inputted to the second delay circuit 22b. Accordingly, the gate drive signal can be supplied from the drive circuit 10 to the plurality of semiconductor switching elements almost at the same time. Thus, delay times set in the delay circuits (first delay circuit 20b, second delay circuit 22b) can be shortened while variations in operation of the plurality of semiconductor switching elements are reduced.

In Embodiment 1 of the present invention, the first voltage and the second voltage are supplied from the one constant voltage circuit 16 to the plurality of output circuits. Accordingly, the plurality of output circuits use the first and second voltages common thereto, and variations in operation of the plurality of semiconductor switching elements can be reduced.

The drive circuit 10 according to Embodiment 1 of the present invention can be variously modified within a range in which features thereof are not lost. For example, the signal transmission circuit 14 may be omitted. Moreover, the first output circuit 20 applies the first voltage VEp to the first terminal 24 only during a predetermined first period when the gate drive signal rises; after the first period has elapsed, increases the voltage of the gate drive signal and applies the gate drive signal with the increased voltage to the first terminal 24; and applies the second voltage VEn to the first terminal 24 only during a predetermined second period when the gate drive signal falls. A first output circuit having a configuration different from that of the above-described first output circuit 20 may be used as long as the first output circuit has the above-described function.

The second output circuit 22 is supposed to apply the first voltage VEp to the second terminal 26 only during a first period when the gate drive signal rises; after the first period has elapsed, increase the voltage of the gate drive signal and apply the gate drive signal with the increased voltage to the second terminal 26; and apply the second voltage VEn to the second terminal 26 only during a second period when the gate drive signal falls. A second output circuit having a configuration different from that of the above-described second output circuit 22 may be used as long as the second output circuit has this function.

In Embodiment 1, the drive circuit 10 includes two output circuits, and two semiconductor switching elements are connected to the drive circuit 10. However, the number of output circuits included in the drive circuit 10 and the number of semiconductor switching elements connected in parallel are not limited to specific numbers. For example, in the case where one drive circuit controls three semiconductor switching elements, a lower first voltage VEp and a higher second voltage VEn are used compared to those in the case where two semiconductor switching elements are controlled. In the case where a large number of semiconductor switching elements are controlled, a large current may be concentrated on one semiconductor switching element, but the above-described technique can prevent a large current from flowing through a specific one of the semiconductor switching elements.

These modifications can be appropriately applied to drive circuits and semiconductor devices according to embodiments below. It should be noted that the embodiments below have many things in common with Embodiment 1, and therefore differences from Embodiment 1 will be mainly described.

### Embodiment 2

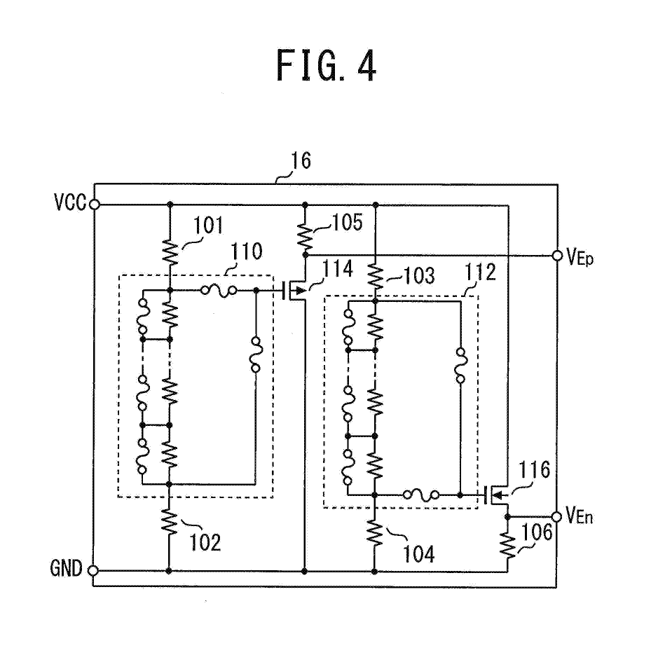

A feature of a drive circuit according to Embodiment 2 is the configuration of a constant voltage circuit. FIG. 4 is a circuit diagram of the constant voltage circuit 16 according to Embodiment 2. The constant voltage circuit 16 includes resistors 101, 102, 103, 104, 105, and 106, variable resistive components 110 and 112, and MOSes 114 and 116. The variable resistive component 110 has a plurality of fuses between the resistor 101 and the resistor 102. The variable resistive component 112 has a plurality of fuses between the resistor 103 and the resistor 104. The resistance values of the variable resistive components 110 and 112 can be freely changed by selecting whether each fuse is irradiated with a laser. By setting the resistance values of the variable resistive components 110 and 112 to desired values to control the gate input voltages of the MOSes 114 and 116, the first voltage VEp and the second voltage VEn can be controlled (adjusted).

The MOSes 114 and 116 have source follower configurations: the drain terminals thereof are respectively connected to GND and VCC, and the source terminals thereof are respectively connected to terminals (denoted by VEp and VEn). The resistors 105 and 106, connected to the source terminals of the MOSes 114 and 116, are inserted to prevent the source terminals of the MOSes 114 and 116 from entering a high-impedance state. In the case where there is no concern that the source terminals of the MOSes 114 and 116 will enter a high-impedance state, the resistors 105 and 106 may be omitted. Any one of the resistors 101 and 102 may be a constant current source. Moreover, any one of the resistors 103 and 104 may be a constant current source.

The constant voltage circuit 16 configured to include fuses as described above makes it possible to adjust the first voltage VEp and the second voltage VEn. Thus, the first voltage VEp and the second voltage VEn can be set to optimum values for a plurality of semiconductor switching elements by taking into account variations in Vth of the semiconductor switching elements.

As long as the constant voltage circuit includes a fuse which changes the first voltage VEp or the second voltage VEn between before and after fusing, the configuration of the constant voltage circuit may be appropriately changed.

### Embodiment 3

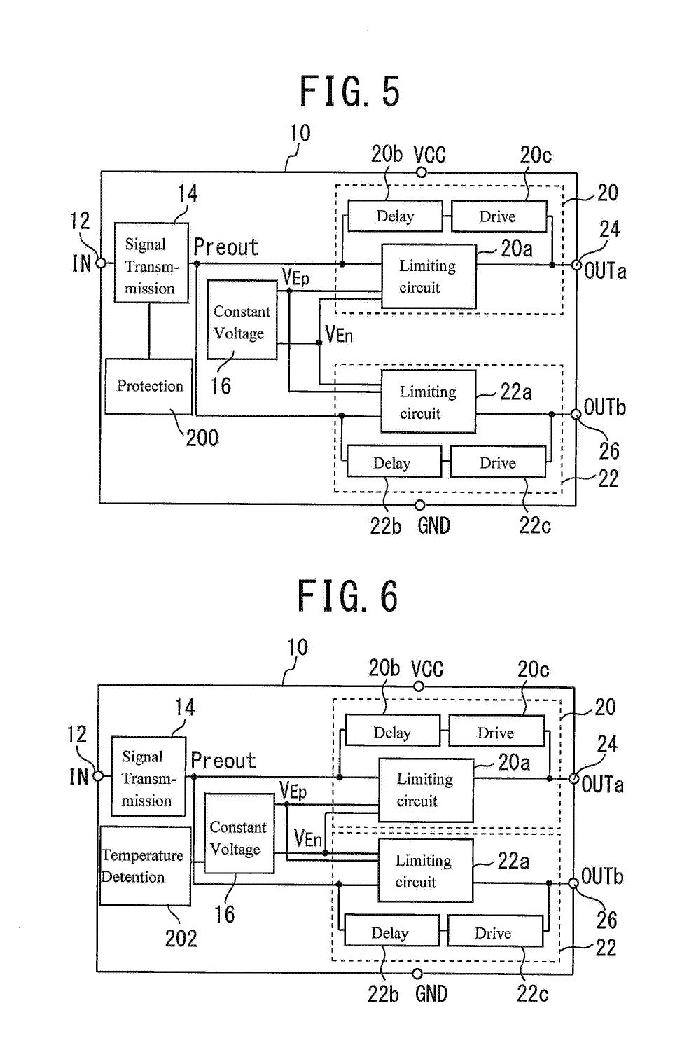

A feature of the drive circuit according to Embodiment 3 is that a protecting circuit is provided therein. FIG. 5 is a block diagram of the drive circuit according to Embodiment 3 of the present invention. This drive circuit has one protecting circuit 200 connected to the signal transmission circuit 14. The protecting circuit 200 is intended to block the gate drive signal Preout when the supply voltage (VCC) of the first drive circuit 20c or the second drive circuit 22c becomes lower than a predetermined value, thus stopping the outputs of the first drive circuit 20c and the second drive circuit 22c.

Since the one protecting circuit 200 performs operation for protecting a plurality of drive circuits as described above, the plurality of drive circuits can be evenly protected. Specifically, since the protecting circuit 200 can stop the outputs of the plurality of drive circuits at the same time, the plurality of semiconductor switching elements can be turned off at the same time. Further, since the signal transmission circuit 14, the constant voltage circuit 16, the first output circuit 20, the second output circuit 22, and the protecting circuit 200 are formed as one IC, the device configuration can be made simpler than in the case where a protecting circuit is provided outside the drive circuit. It should be noted that one protecting circuit may be connected to the first drive circuit 20c and the second drive circuit 22c to stop the outputs thereof, or the outputs thereof may be stopped in another way.

### Embodiment 4

FIG. 6 is a block diagram of a drive circuit according to Embodiment 4. This drive circuit includes a temperature detection circuit 202 for measuring the temperature of the drive circuit. The temperature detection circuit 202 measures the temperature of the drive circuit 10 by a publicly-known method. The temperature detection circuit 202 is connected to the constant voltage circuit 16. The constant voltage circuit 16 acquires information on the temperature measured by the temperature detection circuit 202, and, if the temperature of the drive circuit 10 is higher than a predetermined temperature, decreases the first voltage VEp and increases the second voltage VEn. Linking the information on temperature to the output voltages (first voltage and second voltage) in this way can be realized by a publicly-known method using, for example, an amplifier.

Major heat sources in a semiconductor device are semiconductor switching elements. Accordingly, when the temperature of the drive circuit 10 is high, the temperatures of the semiconductor switching elements are expected to be high. Accordingly, when the temperature of the drive circuit 10 is higher than a predetermined temperature, the temperatures of the semiconductor switching elements are considered to be significantly high. When a current is concentrated on one of the plurality of semiconductor switching elements at such high temperature, the semiconductor switching element becomes deteriorated. Accordingly, by decreasing the first voltage VEp and increasing the second voltage VEn as described above, the value of a current concentrated on one of the plurality of semiconductor switching elements can be reduced.

In the case where the temperature detection circuit is provided in the drive circuit, the temperature detection circuit measures the temperature of the drive circuit to indirectly detect the temperatures of the semiconductor switching elements. In the case where the temperatures of the semiconductor switching elements are desired to be directly measured, the temperature detection circuit may be provided on or near the semiconductor switching elements.

### Embodiment 5

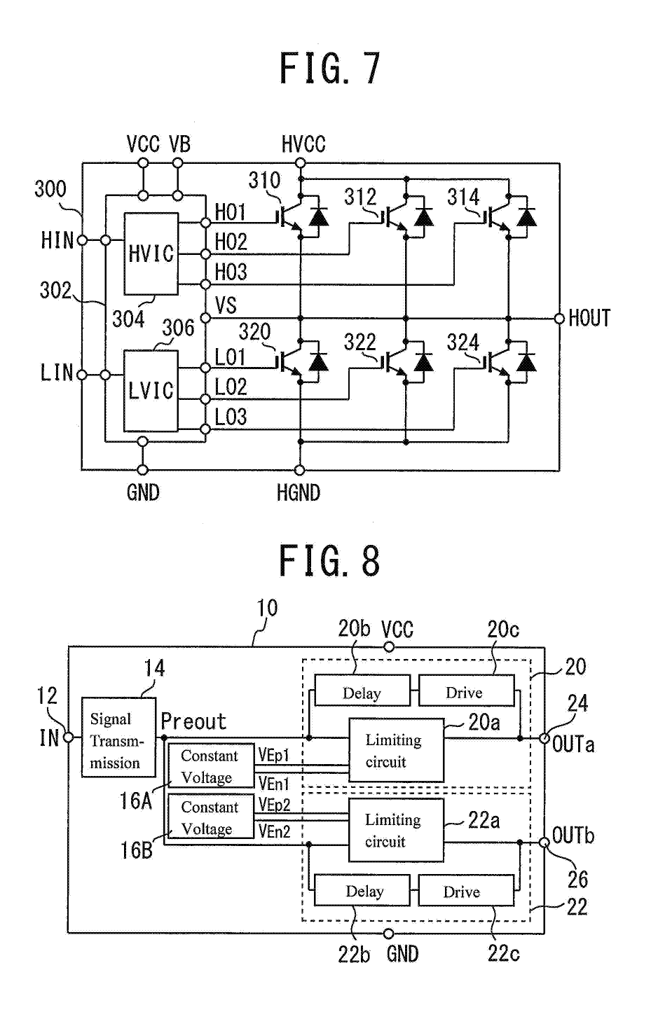

FIG. 7 is a circuit diagram of a semiconductor device 300 according to Embodiment 5. The semiconductor device 300 includes a drive module 302 in which drive circuits 304 and 306 are formed. Each of the drive circuits 304 and 306 basically has the same configuration as the drive circuit 10 in FIG. 1 described in Embodiment 1, but differs from the drive circuit 10 in FIG. 1 in that each of the drive circuits 304 and 306 has three output circuits and three output terminals.

The drive circuit 304 receives a gate drive signal inputted from an input terminal HIN, and outputs the gate drive signal to a first terminal HO1, a second terminal HO2, and a third terminal HO3. The drive circuit 306 receives a gate drive signal inputted from an input terminal LIN, and outputs the gate drive signal to a first terminal LO1, a second terminal LO2, and a third terminal LO3.

In each of the drive circuit 304 and the drive circuit 306, one constant voltage circuit supplies three output circuits with a first voltage and a second voltage. Moreover, one signal transmission circuit supplies the three output circuits with the gate drive signal.

A gate of a semiconductor switching element 310 is connected to the first terminal HO1, a gate of a semiconductor switching element 312 is connected to the second terminal HO2, and a gate of a semiconductor switching element 314 is connected to the third terminal HO3. The semiconductor switching elements 310, 312, and 314 are connected in parallel. The semiconductor switching elements 310, 312, and 314 are semiconductor switching elements on a high-potential side.

A gate of a semiconductor switching element 320 is connected to the first terminal LO1, a gate of a semiconductor switching element 322 is connected to the second terminal LO2, and a gate of a semiconductor switching element 324 is connected to the third terminal LO3. The semiconductor switching elements 320, 322, and 324 are connected in parallel. The semiconductor switching elements 320, 322, and 324 are semiconductor switching elements on a low-potential side.

The plurality of output circuits (each of the drive circuits 304 and 306 has three output circuits) apply the first voltage VEp to the plurality of terminals (first terminals HO1 and LO1, second terminals HO2 and LO2, third terminals HO3 and LO3) only during a predetermined first period when the gate drive signal rises. After the first period has elapsed, the plurality of output circuits increase the voltage of the gate drive signal and apply the gate drive signal with the increased voltage to the plurality of terminals. The plurality of output circuits apply the second voltage VEn to the plurality of terminals only during a predetermined second period when the gate drive signal falls.

When the gate drive signal rises, the gate voltages of the semiconductor switching elements 310, 312, and 314 driven in parallel are controlled to be the first voltage VEp or less, and therefore a too large current is prevented from flowing through any one of the elements. Moreover, when the gate drive signal falls, the gate voltages of the semiconductor switching elements 310, 312, and 314 driven in parallel are controlled to be the second voltage VEn or more, and therefore a too large current is prevented from flowing through any one of the elements. The same effects can be obtained for the semiconductor switching elements 320, 322, and 324.

Accordingly, the present embodiment can prevent a large current from flowing through a specific semiconductor switching element due to variations in switching (timing). Moreover, since each semiconductor switching element is controlled by an individual gate drive signal, there is no concern about gate oscillation. Further, since the gate voltages of the semiconductor switching elements do not need to be detected, control is easily performed.

The semiconductor switching elements connected in parallel may be ones in which SOAs (safe operating areas) are set. In that case, by setting the first voltage VEp and the second voltage VEn such that the values of maximum currents which can flow through the semiconductor switching elements are within the SOAs, a more stable, large-current-capacity semiconductor device can be realized.

The first voltage VEp is preferably set such a value that a current of the rated current or less flows through one of the plurality of semiconductor switching elements which has been turned on first when the gate drive signal rises. Moreover, the second voltage VEn is preferably set to such a value that a current of the rated current or less flows through one of the plurality of semiconductor switching elements which has been turned off last when the gate drive signal falls.

The number of semiconductor switching elements controlled by one drive circuit may be any number larger than one. The number of output circuits and the number of terminals are equal to the number of semiconductor switching elements to be controlled. Instead of providing two drive circuits in the drive module 302 individually, these two drive circuits may be formed as one IC (integrated circuit). Moreover, the gate drive signal may be inputted from one terminal to the drive circuits 304 and 306. A gate resistor may be provided between the output terminal of the drive circuit and the gate of the semiconductor switching element.

While IGBTs have been illustrated as semiconductor switching elements, switching elements of other type may be used. The supply voltage VB may be generated within the semiconductor device instead of being supplied from the outside of the semiconductor device 300 as shown in FIG. 7. Such supply voltage generation may be performed using a publicly-known technique, such as a technique using a boot strap circuit including a boot strap diode.

With two configurations which are the same as the configuration shown in FIG. 7, a bridge circuit can be formed. With three configurations, a three-phase AC inverter can be formed. The drive circuits 304 and 306 may be any of the drive circuits described in the above-described embodiments.

### Embodiment 6

In Embodiments 1 to 5, one constant voltage circuit is provided in one drive circuit. However, there are cases where providing a plurality of constant voltage circuits in one drive circuit is appropriate. Such cases will be described in Embodiments 6 and 7. FIG. 8 is a block diagram of a drive circuit according to Embodiment 6. This drive circuit 10 includes a first constant voltage circuit 16A for generating a first voltage VEp1 and a second voltage VEn1 and a second constant voltage circuit 16B for generating a third voltage VEp2 and a fourth voltage VEn2. The first voltage VEp1 is different from the third voltage VEp2, and the second voltage VEn1 is different from the fourth voltage VEn2.

The first output circuit 20 is connected to the first constant voltage circuit 16A, receives the first voltage VEp1 and the second voltage VEn1, and receives the gate drive signal. The second output circuit 22 is connected to the second constant voltage circuit 16B, receives the third voltage VEp2 and the fourth voltage VEn2, and receives the gate drive signal.

The first output circuit 20 applies the first voltage VEp1 to the first terminal 24 only during a predetermined first period when the gate drive signal rises; after the first period has elapsed, increases the voltage of the gate drive signal and applies the gate drive signal with the increased voltage to the first terminal 24; and applies the second voltage VEn1 to the first terminal 24 only during a predetermined second period when the gate drive signal falls.

The second output circuit 22 applies the third voltage VEp2 to the second terminal 26 only during the first period when the gate drive signal rises; after the first period has elapsed, increases the voltage of the gate drive signal and applies the gate drive signal with the increased voltage to the second terminal 26; and applies the fourth voltage VEn2 to the second terminal 26 only during the second period when the gate drive signal falls. The first constant voltage circuit 16A, the second constant voltage circuit 16B, the first output circuit 20, and the second output circuit 22 are provided in one IC.

For example, there are cases where a gate of an IGBT is connected to the first terminal 24 and where a gate of a MOSFET connected in parallel with the IGBT is connected to the second terminal 26. Electrical characteristics of an IGBT and electrical characteristics of a MOSFET are different from each other. Accordingly, it is preferable that different upper voltage limits in the first period (period from t1 to t2 in FIG. 3) and different lower voltage limits in the second period (period from t3 to t4 in FIG. 3) are set for the IGBT and the MOSFET.

Accordingly, in Embodiment 6 of the present invention, since the first constant voltage circuit 16A and the second constant voltage circuit 16B are provided, different voltages can be applied to the IGBT and the MOSFET in the first period and the second period. Moreover, since the first constant voltage circuit 16A, the second constant voltage circuit 16B, the first output circuit 20, and the second output circuit 22 are provided in one IC, a switching timing difference (imbalance) between the plurality of semiconductor switching elements can be reduced.

Providing a plurality of constant voltage circuits as described above is effective in the case where different kinds of semiconductor switching elements are driven by one drive circuit. Naturally, the plurality of semiconductor switching elements are not limited to an IGBT and a MOSFET, and publicly-known semiconductor switching elements can be appropriately used.

### Embodiment 7

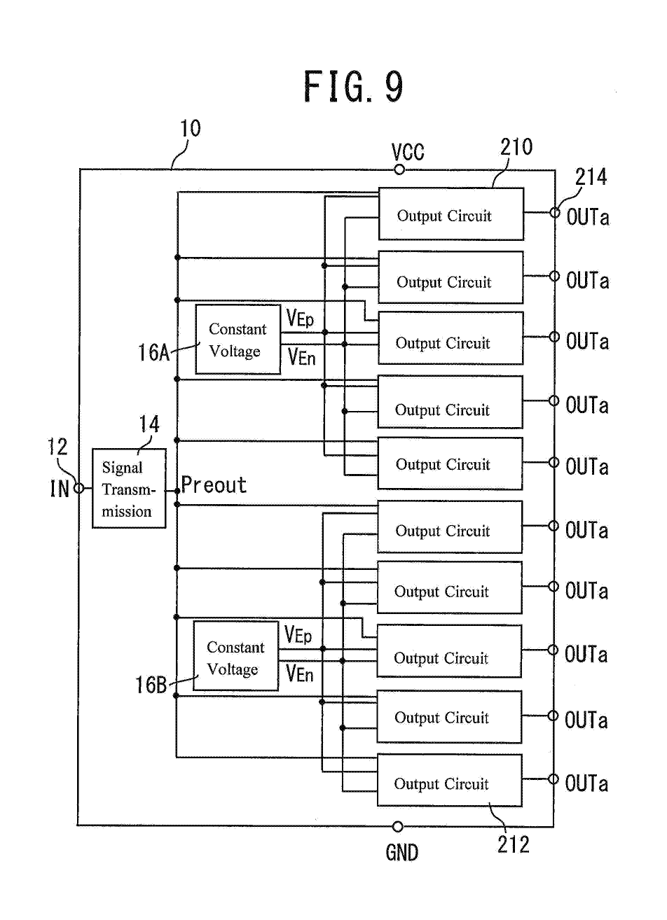

FIG. 9 is a block diagram of a drive circuit according to Embodiment 7. This drive circuit 10 is intended to control ten semiconductor switching elements connected in parallel, and therefore includes ten output circuits. Specifically, the drive circuit 10 includes five first output circuits 210 and five second output circuits 212. The first constant voltage circuit 16A supplies the first voltage VEp and the second voltage VEn to the five first output circuits 210. The second constant voltage circuit 16B also supplies the first voltage VEp and the second voltage VEn to the five second output circuits 212. The first voltage generated by the first constant voltage circuit 16A and the first voltage generated by the second constant voltage circuit 16B are equal, and the second voltage generated by the first constant voltage circuit 16A and the second voltage generated by the second constant voltage circuit 16B are equal.

The first constant voltage circuit 16A is connected to the five first output circuits 210. Each of the five first output circuits 210 receives the first voltage and the second voltage, and receives the gate drive signal. The second constant voltage circuit 16B is connected to the five second output circuits 212. Each of the five second output circuits 212 receives the first voltage and the second voltage, and receives the gate drive signal. The outputs of the ten output circuits in total are respectively connected to terminals 214.

Each of the ten output circuits has a configuration equivalent to that of the first output circuit 20 in FIG. 1. The first output circuits 210 and the second output circuits 212 apply the first voltage VEp to the plurality of terminals only during a predetermined first period when the gate drive signal rises; after the first period has elapsed, increase the voltage of the gate drive signal and apply the gate drive signal with the increased voltage to the plurality of terminals; and apply the second voltage VEn to the plurality of terminals only during a predetermined second period when the gate drive signal falls. The first constant voltage circuit 16A, the second constant voltage circuit 16B, the plurality of first output circuits 210, and the plurality of second output circuits 212 are formed in one IC.

In the case where a large number of (e.g., ten) semiconductor switching elements connected in parallel are controlled by one drive circuit, a large number of (e.g., ten) output circuits are also needed. In this case, if the first voltage and the second voltage are supplied to the ten output circuits from one constant voltage circuit, interconnections for supplying voltages become long, and the values of the constant voltages supplied to the plurality of output circuits may vary.

In such a case, preparing a plurality of constant voltage circuits as in the present embodiment makes it possible to make the values of voltages supplied to a plurality of output circuits substantially equal. In this case, it is important to make the values of the constant voltages of the plurality of constant voltage circuits even. To make the values of the constant voltages of the plurality of constant voltage circuits even, for example, using the circuit in FIG. 4 as a constant voltage circuit is effective.

Since the first constant voltage circuit 16A, the second constant voltage circuit 16B, the plurality of first output circuits 210, and the plurality of second output circuits 212 are formed in one IC, variations in control of the plurality of output circuits can be reduced.

The number of output circuits is not limited to ten. Even if the number of output circuits is about four, in the case where the values of the constant voltages supplied to the plurality of output circuits need to be made even, a plurality of constant voltage circuits should be provided. It should be noted that features of the drive circuits described in the embodiments described above may be appropriately combined to improve advantageous effects of the present invention.

### DESCRIPTION OF SYMBOLS

10 drive circuit, 12 input terminal, 14 signal transmission circuit, 16 constant voltage circuit, 20 first output circuit, 20a first limiting circuit, 20b first delay circuit, 20c first drive circuit, 22 second output circuit, 22a second limiting circuit, 22b second delay circuit, 22c second drive circuit, 24 first terminal, 26 second terminal, 200 protecting circuit, 202 temperature detection circuit

1. A drive circuit comprising:
one constant voltage circuit for generating a first voltage and a second voltage;
a first output circuit connected to the constant voltage circuit to receive the first voltage and the second voltage and receive a gate drive signal;
a second output circuit connected to the constant voltage circuit to receive the first voltage and the second voltage and receive the gate drive signal;
a first terminal connected to an output of the first output circuit; and
a second terminal connected to an output of the second output circuit,
wherein the first output circuit applies the first voltage to the first terminal only during a predetermined first period when the gate drive signal rises; after the first period has elapsed, increases a voltage of the gate drive signal and applies the gate drive signal with the increased voltage to the first terminal; and applies the second voltage to the first terminal only during a predetermined second period when the gate drive signal falls, and
the second output circuit applies the first voltage to the second terminal only during the first period when the gate drive signal rises; after the first period has elapsed, increases a voltage of the gate drive signal and applies the gate drive signal with the increased voltage to the second terminal; and applies the second voltage to the second terminal only during the second period when the gate drive signal falls.

2. The drive circuit according to claim 1, wherein
the first output circuit comprises:
a first limiting circuit for applying the first voltage to the first terminal during the first period and applying the second voltage to the first terminal during the second period;
a first delay circuit for outputting the gate drive signal with a delay; and
a first drive circuit for amplifying an output of the first delay circuit and applying the amplified output to the first terminal during a period after the first period and before start of the second period, and
the second output circuit comprises:
a second limiting circuit for applying the first voltage to the second terminal during the first period and applying the second voltage to the second terminal during the second period;
a second delay circuit for outputting the gate drive signal with a delay; and
a second drive circuit for amplifying an output of the second delay circuit and applying the amplified output to the second terminal during a period after the first period and before start of the second period.

3. The drive circuit according to claim 2, further comprising:
at least one of a filter circuit, a delay circuit, and a level shifter circuit; and
one signal transmission circuit for outputting the gate drive signal to the first output circuit and the second output circuit.

4. The drive circuit according to claim 3, wherein the constant voltage circuit, the first output circuit, the second output circuit, and the signal transmission circuit are formed in one IC.

5. The drive circuit according to claim 2, wherein each of the first limiting circuit and the second limiting circuit comprises a source follower circuit.

6. The drive circuit according to claim 1, wherein the constant voltage circuit comprises a fuse for changing any one of the first voltage and the second voltage between before and after fusing.

7. The drive circuit according to claim 3, further comprising:
one protecting circuit for stopping outputs of the first drive circuit and the second drive circuit when a supply voltage of any one of the first drive circuit and the second drive circuit becomes lower than a predetermined value,
wherein the constant voltage circuit, the first output circuit, the second output circuit, the signal transmission circuit, and the protecting circuit are formed in one IC.

8. The drive circuit according to claim 1, further comprising:
a temperature detection circuit for measuring a temperature of the drive circuit,
wherein the constant voltage circuit acquires information on the temperature measured by the temperature detection circuit, and, if the temperature of the drive circuit becomes higher than a predetermined temperature, decreases the first voltage and increases the second voltage.

9. A semiconductor device comprising:
one constant voltage circuit for generating a first voltage and a second voltage;
a plurality of output circuits connected to the constant voltage circuit to receive the first voltage and the second voltage and receive a gate drive signal;
a plurality of terminals connected to outputs of the plurality of output circuits; and
a plurality of semiconductor switching elements connected to the plurality of terminals and connected in parallel,
wherein the plurality of output circuits apply the first voltage to the plurality of terminals only during a predetermined first period when the gate drive signal rises; after the first period has elapsed, increase a voltage of the gate drive signal and apply the gate drive signal with the increased voltage to the plurality of terminals; and apply the second voltage to the plurality of terminals only during a predetermined second period when the gate drive signal falls.

10. The semiconductor device according to claim 9, wherein
the first voltage is set to a value allowing a current of a rated current or less to flow through one of the plurality of semiconductor switching elements which is turned on first when the gate drive signal rises, and
the second voltage is set to a value allowing a current of a rated current or less to flow through one of the plurality of semiconductor switching elements which is turned off last when the gate drive signal falls.

11. The semiconductor device according to claim 9, further comprising:
a temperature detection circuit for measuring temperatures of the plurality of semiconductor switching elements,
wherein the constant voltage circuit acquires information on the temperatures measured by the temperature detection circuit, and, if the temperatures of the plurality of semiconductor switching elements become higher than a predetermined temperature, decreases the first voltage and increases the second voltage.

12. A drive circuit comprising:
a first constant voltage circuit for generating a first voltage and a second voltage;
a second constant voltage circuit for generating a third voltage and a fourth voltage;
a first output circuit connected to the first constant voltage circuit to receive the first voltage and the second voltage and receive a gate drive signal;
a second output circuit connected to the second constant voltage circuit to receive the third voltage and the fourth voltage and receive the gate drive signal;
a first terminal connected to an output of the first output circuit; and
a second terminal connected to an output of the second output circuit,
wherein the first output circuit applies the first voltage to the first terminal only during a predetermined first period when the gate drive signal rises; after the first period has elapsed, increases a voltage of the gate drive signal and applies the gate drive signal with the increased voltage to the first terminal, and applies the second voltage to the first terminal only during a predetermined second period when the gate drive signal falls,
the second output circuit applies the third voltage to the second terminal only during the first period when the gate drive signal rises; after the first period has elapsed, increases a voltage of the gate drive signal and applies the gate drive signal with the increased voltage to the second terminal; and applies the fourth voltage to the second terminal only during the second period when the gate drive signal falls, and
the first constant voltage circuit, the second constant voltage circuit, the first output circuit, and the second output circuit are formed in one IC.

13. A drive circuit comprising:
a first constant voltage circuit for generating a first voltage and a second voltage;
a second constant voltage circuit for generating voltages equal to the first voltage and the second voltage;
a plurality of first output circuits connected to the first constant voltage circuit to receive the first voltage and the second voltage and receive a gate drive signal;
a plurality of second output circuits connected to the second constant voltage circuit to receive the first voltage and the second voltage and receive the gate drive signal; and
a plurality of terminals connected to outputs of the plurality of first output circuits and outputs of the plurality of second output circuits,
wherein the plurality of first output circuits and the plurality of second output circuits apply the first voltage to the plurality of terminals only during a predetermined first period when the gate drive signal rises; after the first period has elapsed, increase a voltage of the gate drive signal and apply the gate drive signal with the increased voltage to the plurality of terminals;
and apply the second voltage to the plurality of terminals only during a predetermined second period when the gate drive signal falls, and
the first constant voltage circuit, the second constant voltage circuit, the plurality of first output circuits, and the plurality of second output circuits are formed in one IC.
